(19) United States
(12) Patent Application Publication
(10) Pub. No.: US 2019/0187180 A1
(43) Pub. Date: Jun. 20, 2019

(54) PROBER

(71) Applicant: TOKYO ELECTRON LIMITED, Tokyo (JP)

(72) Inventor: Shinjiro WATANABE, Nirasaki City (JP)

(21) Appl. No.: 16/223,420

(22) Filed: Dec. 18, 2018

(30) Foreign Application Priority Data
Dec. 20, 2017 (JP) 2017-243827

(51) Int. Cl. G01R 1/067

(52) U.S. Cl. CPC G01R 1/06794

(57) ABSTRACT

A prober for performing inspection comprises a probe position detection camera configured to detect a position of a leading end of the probe for performing a relative position alignment of the electrode of the wafer and the probe, a probe height detector configured to detect a height of the leading end of the probe from a reference surface serving as a reference of a height of the probe position detection camera, an adjustment mechanism configured to adjust a distance between the leading end of the probe and the probe position detection camera based on a detection result of the probe height detector, and a correction mechanism configured to correct the distance between the leading end of the probe and the probe position detection camera based on image data of the probe captured by the probe position detection camera after the distance is adjusted by the adjustment mechanism.

### CROSS-REFERENCE TO RELATED APPLICATION

This application claims the benefit of Japanese Patent Application No. 2017-243827, filed on Dec. 20, 2017, in the Japan Patent Office, the entire contents of which are incorporated herein by reference.

### TECHNICAL FIELD

The present disclosure relates to a prober for performing wafer inspection by contacting a probe with an electrode formed on a wafer such as a semiconductor wafer.

### BACKGROUND

In a semiconductor manufacturing process, a large number of semiconductor devices having a predetermined circuit pattern are formed on a semiconductor wafer. The formed semiconductor devices are sorted into good products and defective products by inspecting for electrical characteristics and the like. The inspection of the electrical characteristics of the semiconductor devices is performed using a prober in a semiconductor wafer state before each semiconductor device is divided. In the prober, a probe card having a large number of probes is installed. In the inspection using the prober, a position alignment of the probes and the electrodes are performed and then brought closer to each other such that the probes installed on the probe card come into contact with the electrodes on the wafer surface on a loading table. Then, in the state where the probes are contacted with respective electrodes with an appropriate stylus pressure, an electric signal is supplied to the wafer, that is, to the semiconductor devices via respective probes, and it is determined whether corresponding semiconductor devices are defective or not based on the electric signal output from the semiconductor devices via the respective probes.

In the prober as described above, the heights of the leading ends of the probes are detected for the purpose of, for example, contacting the probes with the electrodes on the wafer surface with an appropriate stylus pressure. As a method of detecting the height of the leading end of the probe, there is a method in which the leading end of the probe is captured with a camera for a position alignment of the probe and the electrode, and the height of the leading end of the probe is calculated from the image capturing result.

Further, in a known prober, a load sensor to be in contact with a probe is installed on a side of the wafer loading table, the load sensor and the probes are contacted with each other by moving the load sensor, and the heights of the leading ends of the probes are detected based on the moving amount of the load sensor. In such a prober, a camera for a position alignment of the probes and electrodes is moved to a height based on the heights of the leading ends of the probes detected by the load sensor, and the position alignment of the probes and the electrodes is performed based on an image capturing result by the camera.

### SUMMARY

However, in the above-described prober, when the camera for a position alignment is moved to a height based on the height of the leading end of the probe detected by the load sensor, and the position alignment of the probes and the electrodes is performed based on the image capturing result of the camera, the position alignment may not be precisely performed in some cases. Specifically, for example, in the case where a plurality of probes are installed on the probe card and the probe card is tilted, the load sensor detects a leading end of the probe located at the lowest position. Even when the probe card is not tilted, there is a variation in the leading end positions of respective probes due to manufacturing error. Therefore, when the position of the camera is set to a position based on the height of the leading end of a probe detected by the load sensor, for example, a position spaced apart from the detected height by a working distance of the camera, the position of the probe is not precisely detected because a probe deviates significantly from a focus depending on the probe to be captured by the camera, and thus the position alignment of the probes and the electrodes may not be precisely performed.

The present disclosure provides a prober for precisely performing a position alignment of an electrode of a wafer and a probe more reliably.

According to one embodiment of the present disclosure, there is provided a prober for performing inspection by contacting a probe with an electrode formed on a wafer, and the prober comprises a probe position detection camera configured to detect a position of a leading end of the probe for performing a relative position alignment of the electrode of the wafer and the probe, a probe height detector installed separately from the probe position detection camera, and configured to detect a height of the leading end of the probe from a reference surface serving as a reference of a height of the probe position detection camera, an adjustment mechanism configured to adjust a distance between the leading end of the probe and the probe position detection camera based on a detection result of the probe height detector and a correction mechanism configured to correct the distance between the leading end of the probe and the probe position detection camera based on image data of the probe captured by the probe position detection camera after the distance is adjusted by the adjustment mechanism.

According to one embodiment of the present disclosure, the probe height detector includes a contact part configured to be movable in a height direction and contact with the leading end of the probe, and the height of the leading end of the probe from the reference surface is a height of the contact part when the leading end of the probe is in contact with the contact part.

According to one embodiment of the present disclosure, the adjustment mechanism adjusts the distance between the leading end of the probe and the probe position detection camera such that the distance becomes a predetermined working distance of the probe position detection camera.

According to one embodiment of the present disclosure, the correction mechanism corrects the distance between the leading end of the probe and the probe position detection camera based on image data of a plurality of probes captured by the probe position detection camera, the plurality of probes being different from each other.

According to one embodiment of the present disclosure, wherein the adjustment mechanism is further configured to also serve as a correction mechanism.

According to another embodiment of the present disclosure, there is provided a prober for performing inspection by contacting a probe with an electrode formed on a wafer, and the prober comprises a probe position detection camera configured to detect a position of a leading end of the probe, a probe height detector configured to detect a height of the leading end of the probe from a reference surface serving as a reference of a height of the probe position detection camera, an adjustment mechanism configured to adjust a distance between the leading end of the probe and the probe position detection camera based on a detection result of the probe height detector and a correction mechanism configured to correct the distance between the leading end of the probe and the probe position detection camera after the distance is adjusted by the adjustment mechanism based on a detection result of the probe position detection camera.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view illustrating an external configuration of a prober according to an embodiment of the present disclosure.

FIG. 2 is a perspective view illustrating an outline of an internal structure of a main body provided in a prober.

FIG. 3 is an explanatory view of a position alignment process for image units of inspection processing according to an embodiment of the present disclosure.

FIG. 4 is an explanatory view of a height detection unit height acquisition process of inspection processing by according to an embodiment of the present disclosure.

FIG. 5 is an explanatory view of a probe leading end height detection process of inspection processing according to an embodiment of the present disclosure.

FIG. 6 is an explanatory view of a rough position determination process of inspection processing according to an embodiment of the present disclosure.

FIG. 7 is an explanatory view of a high-accuracy position determination process of inspection processing according to an embodiment of the present disclosure.

FIG. 8 is another explanatory diagram of a high-accuracy position determination process of the inspection process according to the embodiment of the present disclosure.

FIG. 9 is an explanatory diagram of an electrode position information acquisition process of inspection processing according to an embodiment of the present disclosure.

FIG. 10 is an explanatory view of an electrical inspection process of inspection processing according to an embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the drawings. In the present specification and the drawings, elements having substantially the same functional configuration are denoted by the same reference numerals and redundant explanations are omitted.

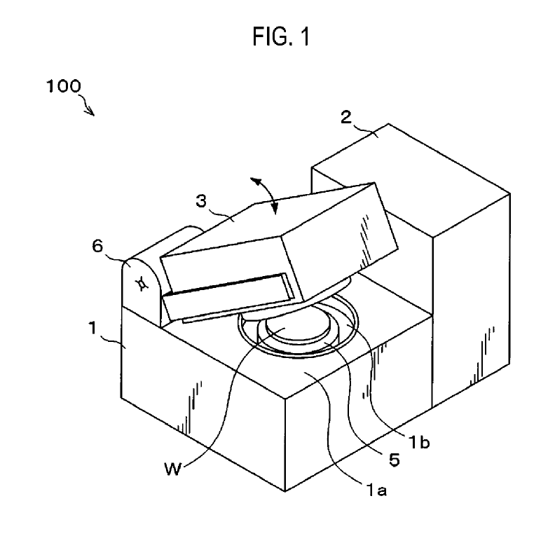

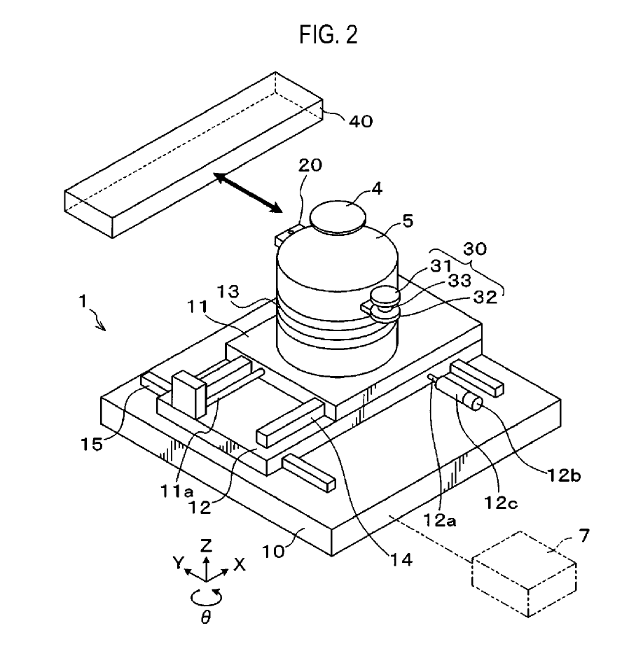

FIG. 1 is a perspective view illustrating an external configuration of a prober 100 according to an embodiment of the present disclosure. FIG. 2 is a perspective view illustrating the outline of the internal structure of a main body 1 (described later) included in the prober 100 of FIG. 1.

The prober 100 inspects the electrical characteristics of a device (not illustrated) such as a semiconductor device formed on a wafer W. As illustrated in FIG. 1, the prober 100 includes a main body 1, a loader part 2 disposed adjacent to the main body 1, and a test head 3 disposed to cover the main body 1.

The main body 1 is a casing inside of which is a cavity, and accommodates a stage 5 on which a wafer W is loaded. An opening part 1b is formed in a ceiling part 1a of the main body 1. The opening part 1b is located above the wafer W loaded on the stage 5, and a substantially disk-shaped probe card holder (not illustrated) is engaged with the opening part 1b. The probe card holder holds the disk-shaped probe card 4 of FIG. 2, and the probe card 4 is disposed to face the wafer W loaded on the stage 5 by the probe card holder.

The loader part 2 takes out a wafer W accommodated in a FOUP (Front Opening Unified Pod) (not illustrated) as a transfer container, and transfers the wafer W to the stage 5 of the main body 1. In addition, the loader part 2 receives the wafer W on which inspection of the electrical characteristics of a device has been completed from the stage 5 and accommodates the wafer W in the FOUP.

The test head 3 has a rectangular parallelepiped shape, and is configured to be pivotable upwards by a hinge mechanism 6 installed in the main body 1. The test head 3 is electrically connected to the probe card 4 via a contact ring (not illustrated) in the state of covering the main body 1 from above. The test head 3 has functions of storing an electric signal indicative of an electric characteristic of a device transmitted from the probe card 4 as measurement data, and determining the presence or absence of an electric defect of the device based on the measurement data.

As illustrated in FIG. 2, the stage 5 is disposed on a base 10, and includes an X direction movement unit 11 that moves in an X direction in the drawing, a Y direction movement unit 12 that moves in a Y direction in the drawing, and a Z direction movement unit 13 that moves in a Z direction illustrated in the drawing.

The X direction movement unit 11 moves the stage 5 with high precision in the X direction by the rotation of a ball screw 11a along the guide rail 14 extending in the X direction. The ball screw 11a is rotated by a motor (not illustrated). In addition, the moving amount of the stage 5 is detectable by an encoder (not illustrated) combined with this motor.

The Y direction movement unit 12 moves the stage 5 with high precision in the Y direction by the rotation of a ball screw 12a along the guide rail 15 extending in the Y direction. The ball screw 12a is rotated by a motor 12b. In addition, the moving amount of the stage 5 is detectable by an encoder 12c combined with this motor 12b.

With the above configuration, the X direction movement unit 11 and the Y direction movement unit 12 move the stage 5 in the X direction and the Y direction orthogonal to each other along a horizontal plane.

The Z direction movement unit 13 has a motor and an encoder (not illustrated), and is configured to move the stage 5 up and down in the Z direction and detect the moving amount of the stage 5. The Z direction movement unit 13 moves the stage 5 toward the probe card 4 so as to bring the probes into contact with the electrodes of the device formed on the wafer W. The stage 5 is disposed to be rotatable in a 0 direction in the drawing on the Z direction movement unit 13 by a motor (not illustrated). The Z direction movement unit 13 adjusts the distance between a probe 4a (described later) and a lower imaging unit 20 (described later) based on the detection result of a height detection unit 30 (described later), and corrects the adjusted distance between the probe 4a and the lower imaging unit 20 based on the detection result of the lower imaging unit 20.

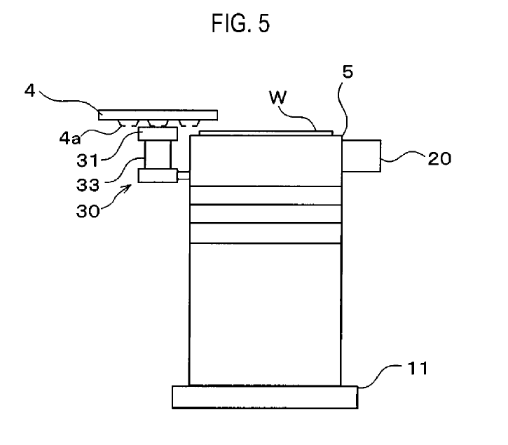

The probe card 4 has a large number of probes 4a (see FIG. 5) on a surface facing the stage 5. In the prober 100, by moving the stage 5 in the horizontal direction (X direction, Y direction, and θ direction) and the vertical direction (Z direction), a relative position of the probe card 4 and the wafer W is adjusted such that the electrodes such as pads of the device formed on the wafer W and the probes 4a are contacted with each other. The test head 3 supplies an inspection current to the device through the respective probes 4a of the probe card 4. The probe card 4 transmits an electric signal indicative of the electrical characteristics of the device to the test head 3. The test head 3 stores transmitted electric signals as measurement data and determines the presence or absence of electrical defects of the device to be inspected. The probes 4a may have any shape as long as they are contacted with and electrically connected to the electrodes of the device.

Inside the main body 1, the lower imaging unit 20 and the height detection unit 30 are disposed.

The lower imaging unit 20 captures the probes 4a formed on the probe card 4. The lower imaging unit 20 includes a camera (not illustrated) including, for example, a Complementary Metal Oxide Semiconductor (CMOS) camera, or a Charge Coupled Device (CCD) camera, and an optical system (not illustrated) that guides light from an imaging object of the camera to the camera. The lower imaging unit 20 captures the probes 4a formed on the probe card 4 by the camera and generates image data. The generated image data is used, for example, for a position alignment of the electrodes on the wafer W and the probes 4a. In other words, the lower imaging unit 20 serves as a probe position detection camera that detects the positions of the leading ends of the probes 4a formed on the probe card 4 so as to perform a relative position alignment between the electrodes formed on the wafer W and the probes 4a. The image data generated by the lower imaging unit 20 is output to the control part 7 described later.

The height detection unit 30 is a probe height detector that is installed separately from the lower imaging unit 20 and detects the heights of the leading ends of the probes 4a from a reference surface serving as a reference of the height of the lower imaging unit 20. The height detection unit 30 includes a load sensor 31 as a contact part that detects the stylus pressure of the probes 4a, a support base 32 that supports the load sensor 31, and a lift mechanism 33 that moves the load sensor 31 in the Z-axis direction, that is, raises or lowers the load sensor 31. The detection result of the load sensor 31 of the height detection unit 30 is output to the control part 7 described later.

The lower imaging unit 20 and the height detection unit 30 described above are fixed to the stage 5 and move in the X direction, the Y direction, and the Z direction together with the stage 5.

Inside the main body 1, an upper imaging unit 40 is disposed at a position between the stage 5 and the probe card 4 in the vertical direction. The upper imaging unit 40 captures, for example, the electrodes of the device formed on the wafer W placed on the stage 5. The upper imaging unit 40 is configured to be movable in the Y direction of FIG. 2 by a driving part (not illustrated).

The upper imaging unit 40 captures, for example, the wafer W. The upper imaging unit 40 includes a camera (not illustrated) including, for example, a CMOS camera or a CCD camera, and an optical system (not illustrated) that guides light from an imaging object of the camera to the camera. The upper imaging unit 40 captures the electrodes of the devices formed on the surface of the wafer W by the camera and generates image data. The generated image data is output to the control part 7 described later.

The prober 100 includes a control part 7 that controls the prober 100. The control part 7 is, for example, a computer, and has a program storage part (not illustrated). The program storage part stores programs that control, for example, the above-described respective imaging units 20 and 40, the height detection unit 30, and respective movement units 11 to 13, and the control inspection processing of a wafer W including the position alignment processing of the electrodes of the wafer W and the probes 4a in the prober 100. The programs may be stored in a computer-readable storage medium such as a computer-readable Hard Disk (HD), a Flexible Disk (FD), a Compact Disk (CD), a Magnet Optical disk (MO), or a memory card, and may be installed in the control part 7 from the storage medium.

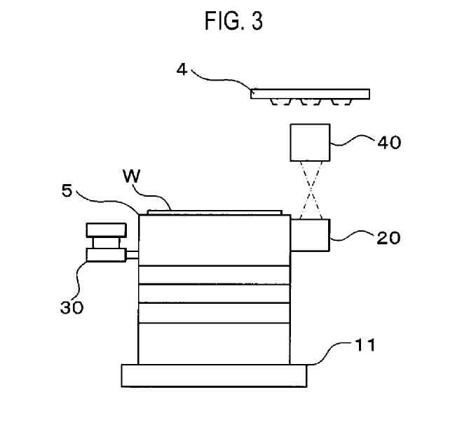

Next, an example of inspection processing on a wafer W using the prober 100 will be described with reference to FIGS. 3 to 10. FIGS. 3 to 10 are explanatory views explaining the respective processes of the inspection processing of this embodiment. FIGS. 3 to 10 schematically illustrate positional relationships of the stage 5, the lower imaging unit 20, the detection unit 30, the upper imaging unit 40, the probe card 4 (probes 4a), and the wafer W.

### (1. Wafer Transfer Process)

In the inspection processing of the present embodiment, for example, first, a wafer W is taken out from a FOUP in the loader part 2 and transferred to the stage 5. Although not illustrated, a device to be subjected to electrical inspection is formed on the surface of the wafer W.

### (2. Position Alignment Process of Imaging Units)

Next, a position alignment of the lower imaging unit 20 and the upper imaging unit 40 is performed. Specifically, as illustrated in FIG. 3, the upper imaging unit 40 and the lower imaging unit 20 are first moved to a point just below the center of the probe center, that is, the center of the probe card 4. Then, the lower imaging unit 20 is moved via the stage 5, and a focal plane of the lower imaging unit 20 and a focal plane of the upper imaging unit 40 are made to coincide with each other using, for example, a target mark (not illustrated). As a result, the position alignment of the lower imaging unit 20 and the upper imaging unit 40 is completed. The X, Y, Z coordinates of the stage 5 after the position alignment is completed are stored in a storage part (not illustrated).

### (3. Probe Height Detection Process)

Subsequently, the height of the probes 4a of the probe card 4 from the reference surface is detected using the height detection unit 30. The reference surface is a surface serving as a reference of the height of, for example, the lower imaging unit 20, and is, for example, the upper surface of the X direction movement unit 11 on which the stage 5 is installed. In the following description, the reference surface means the upper surface of the X direction movement unit 11. However, the reference surface is not limited to this example, and may be, for example, the lower surface of the probe card 4 or the upper surface of the stage 5 when the probes 4a and the stage 5 are contacted with each other, and is not specifically limited as long as it is a surface serving as a reference of the height of, for example, the lower imaging unit 20.

### (3.1. Height Detection Unit Height Acquisition Process)

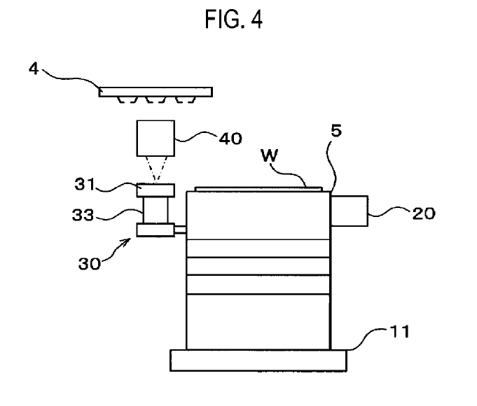

In the probe height detection process, the height detection unit 30 is first moved to a position (hereinafter referred to as “height detection position”) for detecting the height of the probes 4a, and detects a height of the upper surface of the height detection unit 30 from the reference surface at the height detection position. Specifically, as illustrated in FIG. 4, via the stage 5, the height detection unit 30 is moved to a point just below the upper imaging unit 40 located at the probe center. In addition, the load sensor 31 of the height detection unit 30 is raised to the upper end via the lift mechanism 33, and the upper surface of the load sensor 31 is located to be higher than the upper surface of the stage 5. Thereafter, the height detection unit 30 is raised and lowered via the stage 5 such that the focal point of the upper imaging unit 40 is aligned with the upper surface of the load sensor 31. The Z coordinate of the stage 5 at this time is stored in the storage part as the height of the upper surface of the load sensor 31 from the reference surface.

### (3.2. Probe Leading end Height Detection Process)

Following the height detection unit height acquisition process, the heights of the leading ends of the probes 4a are detected using the height detection unit 30. Specifically, as illustrated in FIG. 5, after the upper imaging unit 40 is retracted from the probe center, the load sensor 31 located at the probe center is raised via the stage 5, and the upper surface of the load sensor 31 is brought into contact with the probes 4a. When a predetermined load is detected by the load sensor 31 due to the contact, the raising of the load sensor 31 is stopped. Based on the Z coordinate of the stage 5 at this time and the height of the height detection unit 30 acquired in the height detection unit height acquisition process, the control part 7 calculates the heights of the leading ends of the probes 4a from the reference surface.

### (4. Lower Imaging Unit Position Determination Process)

Then, a position determination is performed in the Z axis direction of the lower imaging unit 20 with respect to the leading ends of the probes 4a.

### (4.1. Rough Position Determination Process)

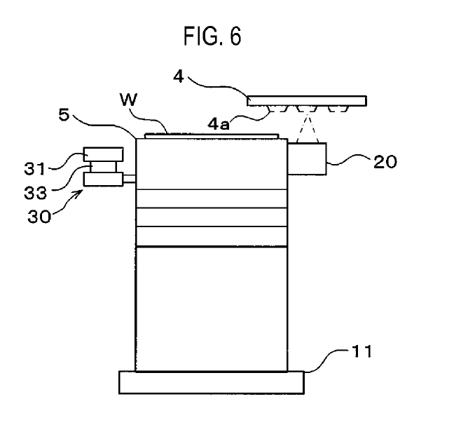

In the lower imaging unit position determination process, rough position determination in the Z axis direction of the lower imaging unit 20 is performed based on the detection result of the height detection unit 30, specifically, based on the heights of the leading ends of the probes 4a from the reference surface using the detection result of the height detection unit 30. For example, as illustrated in FIG. 6, the load sensor 31 is first lowered via the lift mechanism 33, and the lower imaging unit 20 is moved to the probe center via the stage 5. At this time, the lower imaging unit 20 is also moved upwards via the stage 5. Then, based on the heights of the leading ends of the probes 4a from the reference surface calculated in the probe leading end height detection process, the distance between the leading end of a probe 4a (for example, the probe 4a located at the center of the probe card 4) and the lower imaging unit 20 is made to coincide with the pre-stored work distance of the lower imaging unit 20.

### (4.2. High-Precision Position Determination Process)

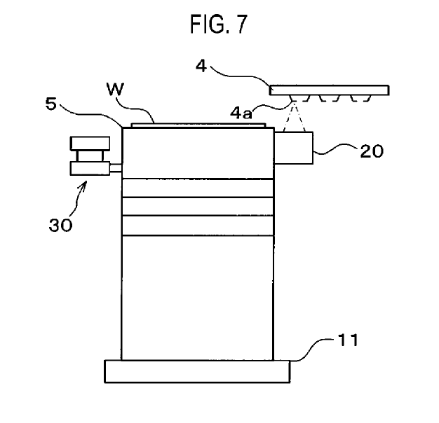

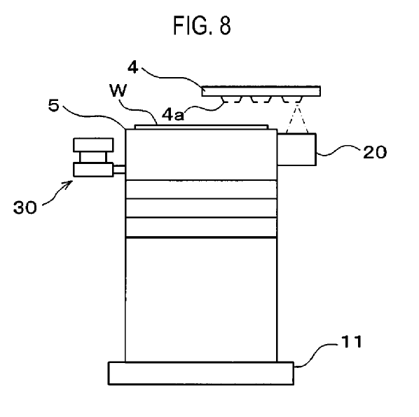

Next, based on the image capturing result of the lower imaging unit 20, the distance between the leading ends of the probes 4a and the lower imaging unit 20 is corrected and high-precision position determination in the Z axis direction of the lower imaging unit 20 is performed with respect to the leading ends of the probes 4a. Specifically, as illustrated in FIG. 7, the lower imaging unit 20 is first moved in the XY plane via the stage 5, and a predetermined probe 4a among the plurality of probes 4a (in the example of the drawing, a probe 4a at one end) is captured by the lower imaging unit 20. Then, based on the image data, specifically, based on the focal degree of a captured image, the distance between the leading end of the predetermined probe 4a and the lower imaging unit 20 is calculated. Further, as illustrated in FIG. 8, the lower imaging unit 20 is moved in the XY plane via the stage 5, and another probe 4a among the plurality of probes 4a (in the example of the drawing, a probe 4a at the other end) is captured by the lower imaging unit 20. The distance between the leading end of the other probe 4a and the lower imaging unit 20 is calculated based on the image data.

Then, the distance between the leading end of the predetermined probe 4a and the lower imaging unit 20 and the distance between the leading end of the other probe 4a and the lower imaging unit 20 are averaged. Then, the distance between the leading end of the probe 4a located at the center of the probe card 4 and the lower imaging unit 20 is corrected to be the above-mentioned averaged value by moving the lower imaging unit 20 in the Z direction via the stage 5. From the working distance of the lower imaging unit 20 and the Z coordinate of the stage 5 at this time, the heights of the leading ends of the probes 4a from the reference surface are recalculated.

In this example, in the high-precision position determination process, two of the plurality of probes 4a are captured and the image capturing result is used for recalculating the height of the leading ends of the probes 4a from the reference surface, but one or three or more probes 4a may be captured and the recalculation may be performed based on the image capturing result.

### (5. Probe XY Position Information Acquisition Process)

After the high-precision position determination process, the lower imaging unit 20 detects the positions of the probes 4a in the XY plane. Specifically, the lower imaging unit 20 is moved in the XY plane via the stage 5 such the center of a probe 4a serving as a reference for a position alignment of the probes 4a and the electrodes of the wafer W (hereinafter, referred to as a “reference probe 4a”) and the center of the captured image of the lower imaging unit 20 coincide with each other. The X and Y coordinate values of the stage 5 at this time serve as position information within the XY plane of the reference probe 4a. The reference probe 4a is predetermined and the number of reference probes 4a may be plural. Further, the high-precision position determination process and the process of detecting the position of the probe 4a in the XY plane by the lower imaging unit 20 may be performed in the same process.

### (6. Electrode Position Information Acquisition Process)

Based on the image capturing result of the upper imaging unit 40, the position of an electrode, which is an electrode of the wafer W and serves as a reference for a position alignment of the probes 4a and the electrodes (hereinafter, referred to as a “reference electrode”) is detected. The reference electrode is predetermined, for example, and the number of the reference electrodes may be plural.

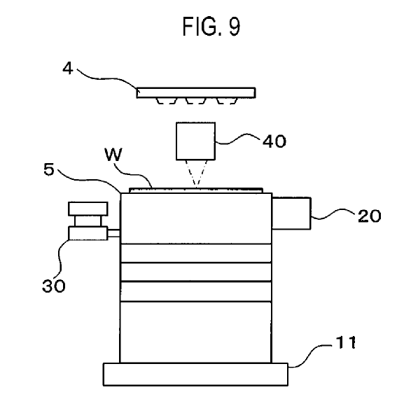

In the electrode position information acquisition process, for example, first, as illustrated in FIG. 9, after moving the stage 5 downwards, the upper imaging unit 40 is moved to the probe center such that the wafer W on the stage 5 is located below the upper imaging unit 40. Next, the upper imaging unit 40 captures the wafer W, and the control part 7 determines the position of the reference electrode based on the image capturing result, for example, by image recognition. Then, the control unit 7 calculates XYZ coordinates of the center of the reference electrode, for example, and stores the coordinates in a storage part (not illustrated).

Relative positions between a plurality of reference positions on the wafer W and the probes 4a may be determined precisely from the respective coordinates by the processes up to the electrode position information acquisition process. That is, the position alignment of the probes 4a and the electrodes of the wafer W may be precisely performed. Each of the above-mentioned coordinates may be managed by the number of encoder pulses in each of the X, Y, Z directions with respect to the case where the stage 5 is located at a predetermined standard position, for example. The reference position information acquisition process may be performed before the probe height detection process.

### (7. Electrical Inspection Process)

After the position alignment of the probes 4a and the electrodes of the wafer W, the electrodes on the wafer W are brought into contact with the probes 4a, and the electrical characteristics of the device including the electrodes are inspected.

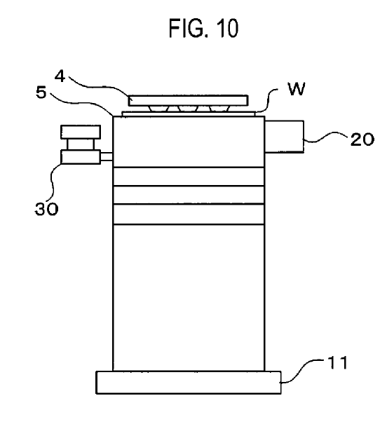

Specifically, based on the XY coordinates of the reference probe 4a obtained in the probe XY position information acquisition process and the XY coordinates of the reference electrode obtained in the electrode position information acquisition process, the position alignments of each of the probes 4a and the electrodes of the wafer W in the XY plane is performed by moving the stage 5 in X and Y directions, as illustrated in FIG. 10. Thereafter, based on the height, from the reference surface, of the leading ends of the probes 4a recalculated in the high-accuracy position determination process and the Z coordinate of the reference electrode obtained in the electrode position information acquisition process, the electrical characteristics of the device are inspected by bringing the probe 4a into contact with the electrodes with a predetermined stylus pressure by moving the stage 5 in the Z direction. Thereafter, the above-described processing is repeated until the inspection of all the devices is completed.

Thereafter, stylus trace inspection may be performed.

As described above, in the prober 100 according to the present embodiment, the probes 4a are captured by the lower imaging unit 20 moved to a position based on the detection result of the height detection unit 30, and the distance between the lower imaging unit 20 and the probes 4a is corrected based on the focal degree of a captured image. When the probes 4a are captured by the lower imaging unit 20 after the correction, a captured image with a focal degree higher than that before the correction is obtained. Therefore, it is possible to detect the position in a direction perpendicular to the height direction of the probes 4a based on the image capturing result, that is, the position on the XY plane more precisely. That is, the position alignments of the probes 4a and the electrodes of the wafer W may be precisely performed.

In the present embodiment, a single Z direction movement unit 13 functions as an adjustment mechanism that adjusts the distance between the leading ends of the probes 4a and the lower imaging unit 20 based on the detection result of the height detection unit 30 and functions as a correction mechanism that corrects the distance between the leading ends of the probes and the lower imaging unit 20 based on the image data of the probes captured by the lower imaging unit 20 after the distance has been adjusted by the adjustment mechanism. Therefore, control is not complicated, and the prober 100 can be reduced in size and cost. However, the adjustment mechanism and the correction mechanism may be separate bodies.

In the example described above, the acquisition of the position information of the probes 4a is performed each time when the electrical characteristics are inspected, but it may be performed only when the probe card 4 is exchanged.

In the above-described high-precision position determination process, unlike the above-described examples, the lower imaging unit 20 may be configured to capture the probes 4a with a moving image, the lower imaging unit 20 may be raised or lowered via the stage 5 such that the lower imaging unit 20 focuses on the leading end of a probe 4a to be captured in the process, and the high-precision position determination of the lower imaging unit 20 may be performed based on the Z coordinate of the stage 5 when the lower imaging unit 20 focuses on the leading end of the probe 4a.

In the forgoing description, electrodes to be inspected are pad electrodes, but may be bump electrodes.

Further, the wafer is not limited to a semiconductor wafer, but may be a flat panel display represented by a glass substrate used for a liquid crystal display device, for example.

Although the embodiments of the present disclosure have been described above with reference to the accompanying drawings, the present disclosure is not limited to such examples. It will be apparent to those ordinarily skilled in the art that various modifications or changes can be conceived within the scope of the idea described in the claims, and it will be understood that the modifications or changes naturally fall within the technical scope of the present disclosure.

The present disclosure is useful for a technique of inspecting a wafer by bringing a probe into contact with an electrode formed on the wafer.

According to the present disclosure, a probe may be captured by a probe position detection camera, the position of which is adjusted such that the distance between the leading end of the probe and the probe position detection camera is a value based on the detection result by the probe height detector, and in order to correct the distance between the leading end of the probe and the probe position detection camera based on the image data, a position alignment of the leading end of the probe and the probe position detection camera may be performed based on the image capturing result with a height focusing degree.

According to the prober of the present disclosure, a position alignment may be performed more accurately.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A prober for performing inspection by contacting a probe with an electrode formed on a wafer, the prober comprising:
a probe position detection camera configured to detect a position of a leading end of the probe for performing a relative position alignment of the electrode of the wafer and the probe;
a probe height detector installed separately from the probe position detection camera, and configured to detect a height of the leading end of the probe from a reference surface serving as a reference of a height of the probe position detection camera;
an adjustment mechanism configured to adjust a distance between the leading end of the probe and the probe position detection camera based on a detection result of the probe height detector; and
a correction mechanism configured to correct the distance between the leading end of the probe and the probe position detection camera based on image data of the probe captured by the probe position detection camera after the distance is adjusted by the adjustment mechanism.

2. The prober of claim 1, wherein the probe height detector includes a contact part configured to be movable in a height direction and contact with the leading end of the probe, and
wherein the height of the leading end of the probe from the reference surface is a height of the contact part when the leading end of the probe is in contact with the contact part.

3. The prober of claim 1, wherein the adjustment mechanism adjusts the distance between the leading end of the probe and the probe position detection camera such that the distance becomes a predetermined working distance of the probe position detection camera.

4. The prober of claim 1, wherein the correction mechanism corrects the distance between the leading end of the probe and the probe position detection camera based on image data of a plurality of probes captured by the probe position detection camera, the plurality of probes being different from each other.

5. The prober of claim 1, wherein the adjustment mechanism is further configured to also serve as a correction mechanism.

6. A prober for performing inspection by contacting a probe with an electrode formed on a wafer, the prober comprising:
a probe position detection camera configured to detect a position of a leading end of the probe;
a probe height detector configured to detect a height of the leading end of the probe from a reference surface serving as a reference of a height of the probe position detection camera;
an adjustment mechanism configured to adjust a distance between the leading end of the probe and the probe position detection camera based on a detection result of the probe height detector; and
a correction mechanism configured to correct the distance between the leading end of the probe and the probe position detection camera after the distance is adjusted by the adjustment mechanism based on a detection result of the probe position detection camera.
